(19) United States
(12) Patent Application Publication
(10) Pub. No.: US 2021/0293995 A1
(43) Pub. Date: Sep. 23, 2021

(54) COVER GLASS AND PROCESS FOR PRODUCING THE SAME

(71) Applicant: AGC Inc., Tokyo (JP)

(72) Inventors: Kensuke FUJII, Tokyo (JP); Shinji KOBUNE, Tokyo (JP); Minoru TAMADA, Tokyo (JP); Hitoshi MISHIRO, Tokyo (JP)

(73) Assignee: AGC Inc., Tokyo (JP)

(21) Appl. No.: 17/335,286

(22) Filed: Jun. 1, 2021

Related U.S. Application Data
(62) Division of application No. 15/387,217, filed on Dec. 21, 2016.

(30) Foreign Application Priority Data
Dec. 28, 2015 (JP) 2015-256531

(51) Int. Cl. G02B 1/115; G02B 1/18; C03C 17/02; C03C 17/245; C03C 17/34; C03C 21/00; C23C 14/00; C23C 14/08; C23C 14/10; C23C 14/34

(52) U.S. Cl. CPC G02B 1/115; C03C 2218/155; C03C 17/02; C03C 17/245; C03C 17/3417; C03C 21/002; C23C 14/0036; C23C 14/083; C23C 14/10; C23C 14/3464; C23C 14/3485; C03C 2217/213; C03C 2217/218; C03C 2217/73; G02B 1/18

(57) ABSTRACT

A cover glass includes a glass substrate and an antireflection film disposed on at least one of main surfaces of the glass substrate, and the at least one of main surfaces of the glass substrate has one or more cracks formed therein, the crack(s) each having a length of 5 μm or less, and a difference Δa* in a* value between any two points within a surface of the cover glass on the side where the antireflection film has been disposed and a difference Δb* in b* value between any two points within the surface of the cover glass on the side where the antireflection film has been disposed satisfy the following expression: √{(Δa*)²+(Δb*)²}≤4.

### CROSS-REFERENCE TO RELATED APPLICATIONS

This application claims priority from Japanese Patent Application No. 2015-256531 filed on Dec. 28, 2015, the entire subject matter of which is incorporated herein by reference.

### BACKGROUND OF THE INVENTION

### Technical Field

The present invention relates to a cover glass and a process for producing the cover glass.

### Background Art

In recent years, image display devices are coming to be increasingly used in various appliances, e.g., navigation systems and speedometers, to be mounted on vehicles, etc. Properties required for cover glasses of such image display devices include diminishing reflection of external light and preventing external light from being reflected in a screen and thereby rendering images less visible, from the standpoints of safety and appearance improvement.

In addition, since such cover glasses are disposed also for a purpose of protecting the image display devices, the cover glasses are required to have excellent strength. Known as a means for improving the strength of a cover glass is, for example, a method in which a glass sheet is subjected to an acid treatment to make it possible to produce a glass sheet having a large iron-ball drop fracture height and a high strength in terms of modulus of rupture in bending (Patent Documents 1 and 2).

Known as a means for preventing light or images from being reflected by or in a glass surface is a technique for reflection prevention which reduces surface reflection. Having been proposed as a technique for reflection prevention is one in which several layers each having appropriate values of refractive index and optical film thickness are stacked as optical interference layers to reduce light reflection occurring at an interface between a laminate and air (Patent Document 3).

Patent Document 1: JP-T-2013-516387 (The term “JP-T” as used herein means a published Japanese translation of a PCT patent application.)

Patent Document 2: JP-T-2014-534945

Patent Document 3: JP-A-2003-215309

### BRIEF SUMMARY OF THE INVENTION

It is thought that in cases where an acid treatment and a formation of an antireflection film are both performed, excellent strength and inhibition of reflection by or in the glass surface can be both attained. However, there is a possibility that the method described above might have a problem in that a color tone of the glass is uneven and varies, that is, unevenness in color results. This problem is thought to arise due to the following.

In an acid treatment step, there are cases where an extremely thin layer which is deficient in cationic components of the glass and which is called a leach-out layer is unevenly formed in the surface of the glass substrate. The leach-out layer differs from the glass substrate in refractive index. Consequently, in cases where an antireflection film is further formed thereon, the leach-out layer behaves as if the layer is a low-refractive-index layer unevenly interposed between the antireflection film and the glass substrate. The unevenness in color is thought to thus result.

An object of an aspect of the present invention is to provide a cover glass which is less apt to suffer color tone unevenness even when the cover glass is produced through both an acid treatment and formation of an antireflection film, and to provide a process for producing the cover glass.

A cover glass of an aspect of the present invention includes a glass substrate and an antireflection film disposed on at least one of main surfaces of the glass substrate, and the at least one of main surfaces of the glass substrate has one or more cracks formed therein, the crack(s) each having a length of 5 μm or less, and a difference Δa* in a* value between any two points within a surface of the cover glass on the side where the antireflection film has been disposed and a difference Δb* in b* value between any two points within the surface of the cover glass on the side where the antireflection film has been disposed satisfy the following expression (1).

√{(Δa*)²+(Δb*)²}≤4 (1)

A process for producing a cover glass of an aspect of the present invention includes a process including an acid treatment step of subjecting surfaces of a glass substrate to an acid treatment, an alkali treatment step of subjecting the glass substrate which has been acid-treated to an alkali treatment, and a step of depositing a antireflection film on a main surface of the glass substrate which has been alkali-treated.

According to the present invention, a cover glass having excellent strength and reduced color tone unevenness and a process for producing the cover glass are provided.

### BRIEF DESCRIPTION OF THE DRAWINGS

FIG. 1A to FIG. 1E are a flowchart which shows steps of one embodiment of the production process of the invention.

### DETAILED DESCRIPTION OF THE INVENTION

The cover glass of an aspect of the present invention is a cover glass including a glass substrate and an antireflection film disposed on at least one of the surfaces of the glass substrate, and the at least one of the main surfaces of the glass substrate has one or more crack(s) formed therein, the crack(s) each having a length of 5 μm or less, and a difference Δa* in a* value between any two points within a surface of the cover glass on the side where the antireflection film has been disposed and a difference Δb* in b* value between any two points within the surface of the cover glass on the side where the antireflection film has been disposed satisfy the following expression (1).

√{(Δa*)²+(Δb*)²}≤4 (1)

Expression (1) is an index to a color distribution in the glass surface. In cases where the left side of the expression is 4 or less, this means that the color distribution in the glass surface is narrow, that is, the color tone unevenness is slight. The left side of expression (1) is preferably 3 or less, more preferably 2 or less.

The Δa* in expression (1) can be determined by selecting any two points within a surface of the cover glass on the side where the antireflection film has been disposed and calculating difference between measured two a* values for the points. The Δb* can be determined in the same manner. a* and b* are color indexes obtained from spectral reflectances measured by examining, with a spectrophotometric colorimeter, that surface of the substrate which has undergone an acid treatment and an antireflection treatment (JIS Z 8729:2004).

Specifically it is preferable that the Δa* and the Δb* should be determined by selecting any square portion of 10 cm² as a measuring range from the surface of the cover glass on the side where the antireflection film has been disposed, dividing the measuring range into 11×11 equal portions, examining all 100 intersections of equally dividing lines for a* values and b* values, determining a maximum value a*ₘₐₓ of the a*values, a minimum value a*ₘᵢₙ of the a*values, a maximum value b*ₘₐₓ of the b*values, and a minimum value b*ₘᵢₙ of the b*values, from the a* values and b* values, and taking a difference (a*ₘₐₓ−a*ₘᵢₙ) between the a*ₘₐₓ and the a*ₘᵢₙ as the Δa* and a difference (b*ₘₐₓ−b*ₘᵢₙ) between the b*ₘₐₓ and the b*ₘᵢₙ as the Δb*.

A shape of the measuring range is not limited to square, so long as the measuring range has an area of 10 cm². In the case where a measuring range is not square, 100 measuring points may be suitably selected so that distributions of color indexes a* and b* in the measuring range can be recognized.

The cover glass of the present invention can satisfy expression (1) because no leach-out layer is present on the glass substrate. The term “leach-out” means a phenomenon in which when a glass surface is treated with a strong acid or the like, cations present in a surface layer part of the glass undergo an exchange reaction with ions of the acid and the surface layer part of the glass thus comes to differ in composition from a bulk part of the glass. The extremely thin layer thus formed in the surface and having a different composition is called a leach-out layer. Examples of methods for avoiding the presence of a leach-out layer include removing the leach-out layer formed by the acid treatment.

The cover glass of the present invention has a degree of ion exchange of desirably 25% or less, preferably 23% or less, more preferably 20% or less, even more preferably 15% or less, especially preferably 10% or less. The degree of ion exchange of the cover glass is preferably 1% or higher. The degree of ion exchange is defined as a value obtained by dividing a content of cations of any kind in an extremely thin surface region of the glass by the content of cations of the same kind in the bulk part of the glass, and is an index to the degree of deficiency of cations in the glass.

Examples of a cation component include sodium, potassium, and aluminum. The term “extremely thin surface region of the glass” means a region ranging from the glass surface to 5 nm. The term “bulk part” means a region extending inward from a depth of 30 nm from the glass surface. In the case where the glass is soda-lime glass, it is preferred to use sodium for an index. In the case where the glass is aluminosilicate glass, it is preferred to use aluminum or potassium for an index. In the present invention, aluminum was used for the index in the case where the glass is aluminosilicate glass. So long as the degree of ion exchange is within that range, the difference in refractive index between the bulk part and the extremely thin surface region is sufficiently negligible and deposition of an antireflection film thereon exerts a negligible influence on the spectrum.

The glass composition of the extremely thin surface region can be determined, for example, by X-ray photoelectron spectroscopy (XPS). The glass composition of the bulk part can be determined, for example, by XPS, X-ray fluorescence analysis (XRF), etc.

Before the removal, a thickness of the ion-exchange layer, i.e., the leach-out layer, as measured from the outermost surface of the glass substrate is preferably 10 nm or less, more preferably 8 nm or less, even more preferably 6 nm or less. It is also preferable that the thickness of the ion-exchange layer, i.e., the leach-out layer, before the removal should be larger than 1 nm. So long as the thickness of the leach-out layer before the removal is 10 nm or less, the leach-out layer can be efficiently removed.

### <Glass Substrate>

As the glass substrate in the present invention, any of glasses having various compositions can be utilized.

For example, it is preferable that the glass to be used in the present invention should contain sodium and have a composition which renders the glass formable and capable of being strengthened by a chemical strengthening treatment. Specific examples of a glass include aluminosilicate glass, soda-lime glass, borosilicate glass, lead glass, alkali-barium glasses, and aluminoborosilicate glass.

The composition of the glass according to the invention is not particularly limited, but examples of the composition of the glass include the following glass compositions. (i) A glass including, in terms of % by mole, from 50 to 80% of SiO₂, from 2 to 25% of Al₂O₃, from 0 to 10% of Li₂O, from 0 to 18% of Na₂O, from 0 to 10% of K₂O, from 0 to 15% of MgO, from 0 to 5% of CaO, and from 0 to 5% of ZrO₂; (ii) a glass which includes, in terms of % by mole, from 50 to 74% of SiO₂, from 1 to 10% of Al₂O₃, from 6 to 14% of Na₂O, from 3 to 11% of K₂O, from 2 to 15% of MgO, from 0 to 6% of CaO, and from 0 to 5% of ZrO₂ and in which a total content of SiO₂ and Al₂O₃ is 75% or less, a total content of Na₂O and K₂O is from 12 to 25%, and a total content of MgO and CaO is from 7 to 15%; (iii) a glass including, in terms of % by mole, from 68 to 80% of SiO₂, from 4 to 10% of Al₂O₃, from 5 to 15% of Na₂O, from 0 to 1% of K₂O, from 4 to 15% of MgO, and from 0 to 1% of ZrO₂; and (iv) a glass which includes, in terms of % by mole, from 67 to 75% of SiO₂, from 0 to 4% of Al₂O₃, from 7 to 15% of Na₂O, from 1 to 9% of K₂O, from 6 to 14% of MgO, and from 0 to 1.5% of ZrO₂ and in which a total content of SiO₂ and Al₂O₃ is from 71 to 75%, a total content of Na₂O and K₂O is from 1 to 20%, and a content of CaO, if it is contained, is less than 1%.

The production method for a glass is not specifically limited. Desired glass raw materials are put into a continuous melting furnace, and the glass raw materials are melted under heat at preferably from 1,500 to 1,600° C., then the melted raw materials are refined and fed into a shaping device to shape the molten glass into a plate-like shape and gradually cooled to produce a glass.

Various methods may be employed for shaping a glass. For example, various shaping processes such as a down-draw process (for example, an overflow down-draw process, a slot-down process, a redraw process, etc.), a float process, a roll-out process, and a pressing process may be employed.

A thickness of a glass is not specifically limited, but for effectively conducting chemical strengthening treatment, in general, the thickness of the glass is preferably 5 mm or less, more preferably 3 mm or less.

It is preferable that the glass substrate should have been chemically strengthened from the standpoint of enhancing the strength of the cover glass. The chemical strengthening treatment is conducted before an acid treatment and before the formation of an antireflection film. A specific method therefor will be described later in a section “Process for Production of the Cover Glass”.

In the cover glass of the present invention, one or more crack(s) present in at least one of main surfaces of the glass substrate each have a length of 5 μm or less. Methods for the acid treatment are not particularly limited, and use can be suitably made of any method whereby the main surface of the glass substrate can be treated and the crack(s) present in the main surface can be shortened.

### <Antireflection Film>

The cover glass of the present invention includes an antireflection film disposed on an acid-treated surface of the glass substrate by performing an antireflection treatment (referred to also as “AR treatment”).

Materials of the antireflection film are not particularly limited, and any of various materials capable of inhibiting the reflection of light can be utilized. For example, the antireflection film may have a configuration containing stacked layers including a high-refractive-index layer and a low-refractive-index layer. The high-refractive-index layer herein is a layer having a refractive index of 1.9 or higher at a wavelength of 550 nm, while the low-refractive-index layer is a layer having a refractive index of 1.6 or less at a wavelength of 550 nm.

The antireflection film may include one high-refractive-index layer and one low-refractive-index layer, or may have a configuration including two or more high-refractive-index layers and two or more low-refractive-index layers. In the case where the antireflection film includes two or more high-refractive-index layers and two or more low-refractive-index layers, it is preferable that the two or more high-refractive-index layers and the two or more low-refractive-index layers should be alternately stacked.

Especially from the standpoint of enhancing an antireflection performance, it is preferable that the antireflection film should be a laminate containing a plurality of stacked layers. For example, the laminate preferably includes two or more and six or less stacked layers in total, and more preferably includes two or more and four or less stacked layers in total. It is preferable that the laminate should include one or more high-refractive-index layers and one or more low-refractive-index layers as described above, and it is preferable that a total number of the high-refractive-index layers and the low-refractive-index layers should be within that range.

Materials of each high-refractive-index layer and each low-refractive-index layer are not particularly limited, and can be selected while taking account of the required degree of reflection prevention, production efficiency, etc. As a material which constitutes the high-refractive-index layer, a material containing one or more elements selected from the group consisting of niobium, titanium, zirconium, tantalum, and silicon can, for example, be advantageously utilized. Specific examples of the material include niobium oxide (Nb₂O₅), titanium oxide (TiO₂), zirconium oxide (ZrO₂), tantalum oxide (Ta₂O₅), and silicon nitride. As a material which constitutes the low-refractive-index layer, a material containing silicon can, for example, be advantageously utilized. Specific examples of the material include silicon oxide (SiO₂), a material including a mixed oxide of Si and Sn, a material including a mixed oxide of Si and Zr, and a material including a mixed oxide of Si and Al.

From the standpoints of production efficiency and a degree of refractive index, it is more preferable that the high-refractive-index layer should be a layer selected from between a niobium-containing layer and a tantalum-containing layer and the low-refractive-index layer should be a silicon-containing layer, and it is even more preferable that the high-refractive-index layer should be a niobium-containing layer. Namely, it is preferable that the antireflection film should be a laminate including one or more niobium-containing layers and one or more silicon-containing layers.

In the cover glass of the present invention, the antireflection film may be disposed on at least one of main surfaces of the glass substrate. However, the cover glass may have a configuration wherein the antireflection film is disposed on each of both main surfaces of the glass substrate.

Methods for forming the antireflection film will be described in detail in the section “Process for Production of the Cover Glass”.

### <Antifouling Film>

The cover glass of the present invention may have an antifouling film (referred to also as “anti finger print (AFP) film”) on the antireflection film, from the standpoint of protecting the surface of the cover glass. The antifouling film can contain, for example, a fluorine-containing organosilicon compound. Fluorine-containing organosilicon compounds which impart antifouling properties, water repellency, and oil repellency can be used without particular limitations. Examples of a fluorine-containing organosilicon compound include fluorine-containing organosilicon compounds having one or more groups selected from the group consisting of polyfluoropolyether groups, polyfluoroalkylene groups, and polyfluoroalkyl groups. The term “polyfluoropolyether group” means a divalent group having a structure in which a polyfluoroalkylene group and an etheric oxygen atom have been alternately bonded.

Commercial products of the fluorine-containing organosilicon compounds having one or more groups selected from the group consisting of polyfluoropolyether groups, polyfluoroalkylene groups, and polyfluoroalkyl groups include KP-801 (trade name; manufactured by Shin-Etsu Chemical Co., Ltd.), KY-178 (trade name; manufactured by Shin-Etsu Chemical Co., Ltd.), KY-130 (trade name; manufactured by Shin-Etsu Chemical Co., Ltd.), KY-185 (trade name; manufactured by Shin-Etsu Chemical Co., Ltd.), and OPTOOL (registered trademark) DSX and OPTOOL AES (both being trade names; manufactured by Daikin Industries, Ltd.). These commercial products can be advantageously used.

The antifouling film is stacked on the antireflection film. In the case where an antireflection film has been deposited on each of both main surfaces of the glass substrate, the antifouling film can be formed on each of both antireflection films. However, use may be made of a configuration wherein the antifouling film is stacked on only either of the both antireflection films. This is because an antifouling film may be disposed at least on a portion where contact with human fingers, etc. and a disposition of the antifouling film can be selected in accordance with the intended use, etc.

### <Contact Angle>

It is preferable that the cover glass of the present invention should have a contact angle of water of 90° or larger. Thus, the cover glass surface has water repellency and oil repellency, and the cover glass is less apt to suffer adhesion of fouling materials thereto. Examples of means for regulating the contact angle of water to 90° or larger include disposing the antifouling film on the antireflection film. For a measurement, about 1 μL droplet of pure water is placed on the surface of the cover glass on the side where the antiglare treatment and antireflection treatment have been performed, and the contact angle of water is measured using a contact angle meter (device name, DM-51; manufactured by Kyowa Interface Science Co., Ltd.),

### <Luminous Reflectance>

It is preferable that the cover glass of the present invention should have a luminous reflectance of 2% or less. So long as the luminous reflectance of the cover glass is within that range, reflection in the cover glass surface can be sufficiently prevented. The luminous reflectance is provided for in JIS Z8701:1999. As a illuminant is used illuminant D65.

### <Process for Production of the Cover Glass>

The cover glass of the present invention can be produced, for example, by the following steps, but usable production processes are not limited thereto. Step 1, chemical strengthening treatment; step 2, acid treatment; step 3, removal of a leach-out layer; step 4, formation of an antireflection film; step 5, formation of an antifouling film.

The chemical strengthening treatment as step 1 and the formation of the antifouling film as step 5 each can be conducted according to need. A printing treatment can also be performed according to need.

It is preferable that the chemical strengthening treatment as step 1 should be conducted before the acid treatment as step 2. From the standpoint of minimizing materials adherent to the glass substrate which is to be subjected to the formation of the antireflection film, it is preferred to conduct the removal of the leach-out layer just before the formation of the antireflection film.

The printing treatment is a treatment in which, when the cover glass is required to be decorated, a pattern according to intended uses or applications, as in, for example, frame printing or logo printing, is printed in suitably selected color(s). Although any of known printing methods is applicable, screen printing, for example, is suitable.

It is preferable that the printing treatment should be conducted between the acid treatment as step 2 and the formation of the antireflection film as step 4 and after the removal of the leach-out layer as step 3, in order to prevent a printed portion from being affected by an etching treatment or other treatment for the removal of the leach-out layer.

In the case where a chemical strengthening treatment and a printing treatment are both performed, it is preferred to conduct the chemical strengthening treatment, the removal of the leach-out layer, and the printing treatment in this order.

It is preferable that the formation of an antifouling film should be conducted as a final step, that is, after the formation of an antireflection film, because the antifouling film is formed in order to protect the glass surface.

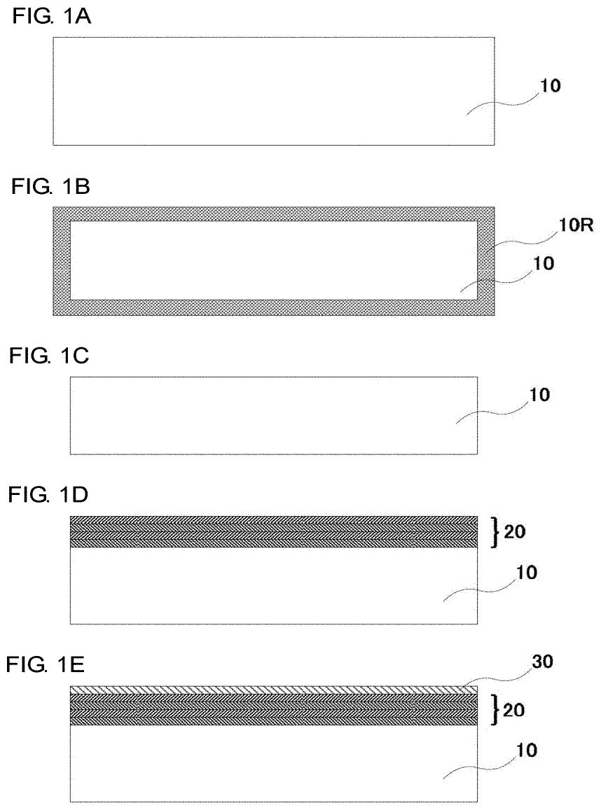

FIG. 1A to FIG. 1E is a flowchart which shows steps of one embodiment of the production process of the present invention. First, a glass substrate 10 is chemically strengthened to form a compressive stress layer (not shown) in a surface layer of the glass substrate 10. Subsequently, main surfaces of the glass substrate 10 are subjected to an acid treatment, thereby removing crack(s) present in the main surfaces of the glass substrate 10 and forming a leach-out layer 10R (FIG. 1A and FIG. 1B). Thereafter, the leach-out layer 10R is removed (FIG. 1C), and an antireflection film 20 is formed on a surface from which the leach-out layer 10R has been removed (FIG. 1D). Furthermore, an antifouling film 30 is formed on the antireflection film 20 (FIG. 1E).

Each step is explained below.

### <Step 1: Chemical Strengthening Treatment>

For the chemical strengthening treatment, known methods can be utilized. For example, chemical strengthening by so-called an ion exchange method is possible, in which metal ions having a small ionic radius (e.g., Na ions) contained in a glass are replaced by metal ions having a larger ionic radius (e.g., K ions) to yield a compressive stress layer in a glass surface and thus improve a strength of the glass.

### <Step 2: Acid Treatment>

An acid treatment is performed by immersing a glass substrate in an acidic solution.

An acidic solution is not particularly limited so long as a pH of the acidic solution is lower than 7, and either a weak acid or a strong acid may be used. Specifically, preferred acids are hydrofluoric acid, hydrochloric acid, nitric acid, sulfuric acid, phosphoric acid, acetic acid, oxalic acid, carbonic acid, citric acid, and the like. These acids may be used alone or in combination of two or more thereof. It is preferable that the acid treatment should be conducted at a temperature of 100° C. or lower, although the temperature varies depending on a kind and concentration of the acid used and on a period.

The period of the acid treatment varies depending on the kind and concentration of the acid used and on the temperature. However, the period of the acid treatment is preferably from 10 seconds to 5 hours from the standpoint of production efficiency, and is more preferably from 1 minute to 2 hours.

The concentration of the acidic solution for the acid treatment varies depending on the kind of the acid used, period, and temperature, but preferably is such a concentration that there is no possibility of corroding a vessel. Specifically, concentrations of from 1 to 20 wt % are preferred.

In the step of the acid treatment, the leach-out described above also occurs simultaneously. A relationship with an etching rate is hence important. Specifically, it is preferred to use concentration and temperature conditions under which the etching rate is at least 1.5 times a rate of the formation of the leach-out layer. The etching rate is more preferably at least 2 times, even more preferably at least 2.5 times, the rate of the formation of the leach-out layer.

### <Step 3: Removal of a Leach-Out Layer>

In step 3, an alkali treatment may be employed for the removal of a leach-out layer.

The alkali treatment is performed by immersing the glass substrate in an alkali solution.

The alkali solution is not particularly limited so long as a pH of the alkali solution exceeds 7, and either a weak base or a strong base may be used. Specifically, preferred bases are sodium hydroxide, potassium hydroxide, potassium carbonate, sodium carbonate, and the like. These bases may be used alone or in combination of two or more thereof.

It is preferable that the alkali treatment should be conducted at a temperature of from 0 to 100° C., more preferably from 10 to 80° C., especially preferably from 20 to 60° C. or lower, although the temperature varies depending on a kind and concentration of the acid used and on a period. Such temperature range is preferred since there is no possibility of corroding the glass.

The period of the alkali treatment varies depending on the kind and concentration of the base used and on the temperature. However, the period of the alkali treatment is preferably from 10 seconds to 20 hours from the standpoint of production efficiency, and is more preferably from 1 minute to 12 hours, even more preferably from 10 minutes to 5 hours.

The concentration of the solution for the alkali treatment is varies depending on the kind of the base used, period, and the temperature, but preferably is from 1 to 20 wt % from the standpoint of a removability of the glass surface.

Examples of methods for grinding with an abrasive material include a method in which a grinding fluid containing an abrasive material selected from among calcium carbonate, cerium oxide, colloidal silica, and the like is used to grind the surface of the glass substrate.

When the leach-out layer is removed by a chemical removal method, it is preferred to remove a glass substrate surface layer down to a depth of 3 nm or larger, preferably 5 nm or larger, more preferably 10 nm or larger. In the case of a physical removal method, it is preferred to remove a glass substrate surface layer down to a depth of 5 nm or larger, preferably 10 nm or larger, more preferably 30 nm or larger. So long as a surface layer is removed in such amount, the leach-out layer can be sufficiently removed. A preferred upper limit of removal amount is 2 μm.

Either the chemical removal method or the physical removal method may be selected. However, the chemical removal method is preferred because the chemical removal method does not form cracks or the like in the glass surface and is free from the possibility that a residue of an abrasive material might foul the glass surface. The chemical removal method and the physical removal method may be conducted in combination.

### <Step 4: Formation of an Antireflection Film>

Methods for depositing an antireflection film are not particularly limited, and any of various film deposition methods can be utilized. It is especially preferred to deposit the antireflection film by a method such as pulse sputtering, AC sputtering, digital sputtering, or the like. By these methods, a dense antireflection film can be formed and durability can be ensured.

When film deposition is conducted, for example, by pulse sputtering, an antireflection film can be deposited on the glass substrate by disposing the glass substrate in a chamber filled with a mixed gas atmosphere containing a mixture of an inert gas and oxygen gas and by using targets suitably selected so as to result in desired compositions.

In this step, a kind of the inert gas in the chamber is not particularly limited, and use can be made of any of various inert gases including argon and helium.

A pressure of the mixture of an inert gas and oxygen gas in the chamber is not particularly limited. However, it is preferred to regulate the pressure thereof so as to be 0.5 Pa or lower, since such a pressure makes it easy to yield an antireflection film having surface roughness within a preferred range. The reason for this is thought to be as follows. In cases where the pressure of the mixture of an inert gas and oxygen gas in the chamber is 0.5 Pa or lower, an average free path of film-forming molecules is ensured and the film-forming molecules carrying a larger amount of energy arrive at the substrate thereby accelerating a rearrangement of film-forming molecules and a relatively dense film having a smooth surface is formed. There is no particular lower limit on the pressure of the mixture of an inert gas and oxygen gas within the chamber, but the pressure thereof is, for example, preferably 0.1 Pa or higher.

### <Step 5: Formation of an Antifouling Film>

Methods for depositing an antifouling film in this embodiment are not particularly limited. However, it is preferred to deposit the film by vacuum deposition using any of the fluorine-containing organosilicon compound materials mentioned above.

In general, fluorine-containing organosilicon compounds are stored in a state of a mixture with a solvent, such as a fluorochemical solvent, for a purpose of, for example, inhibiting a deterioration due to reaction with atmospheric moisture. However, in case where a fluorine-containing organosilicon compound in a state of containing the solvent is subjected to a film deposition step, this organosilicon compound may adversely affect the durability and other properties of a thin film obtained.

It is therefore preferable that either a fluorine-containing organosilicon compound which has undergone a solvent removal treatment before being heated in a heating vessel or a fluorine-containing organosilicon compound which has not been diluted with a solvent (i.e., which contains no solvent added thereto) should be used in this embodiment. For example, it is preferred to use a fluorine-containing organosilicon compound having a solvent concentration of preferably 1 mol % or less, more preferably 0.2 mol % or less. It is especially preferred to use a fluorine-containing organosilicon compound containing no solvent.

Examples of the solvents usable for storing the fluorine-containing organosilicon compound include perfluorohexane, m-xylene hexafluoride (C₆H₄(CF₃)₂), hydrofluoropolyethers, and HFE 7200/7100 (trade names; manufactured by Sumitomo 3M Ltd.; HFE 7200 is represented by C₄F₉C₂H₅ and HFE 7100 is represented by C₄F₉OCH₃).

A treatment for removing the solvent from a solution of a fluorine-containing organosilicon compound in a fluorochemical solvent can be accomplished, for example, by evacuating a vessel which contains the solution of a fluorine-containing organosilicon compound.

It is, however, noted that fluorine-containing organosilicon compounds having a low solvent content or containing no solvent are prone to be deteriorated by contact with air as compared with ones containing a solvent, as stated above.

It is therefore preferable that an atmosphere inside a container in which the fluorine-containing organosilicon compound having a low solvent content (or containing no solvent) is stored should be replaced with an inert gas, e.g., nitrogen, before the container is closed. When this fluorine-containing organosilicon compound is used and handled, it is preferred to minimize the time period during which the compound is exposed to or in contact with the air.

After the fluorine-containing silicon compound is put into a heating vessel, this vessel is evacuated to a vacuum or the atmosphere therein is replaced with an inert gas. It is preferable that heating for film deposition should be initiated immediately thereafter.

By the production process described above, the cover glass of the present invention can be produced.

### EXAMPLES

The present invention is explained below in detail by reference to Examples, but the present invention should not be construed as being limited to the following Examples.

### Example 1

A cover glass was produced in the following manner.

As a glass substrate was used DRAGONTRAIL (registered trademark), manufactured by Asahi Glass Co., Ltd.

(1) First, a chemical strengthening treatment was conducted in the following manner.

The glass substrate from which protective films had been removed was immersed for 2 hours in potassium nitrate kept in a molten state by heating at 450° C. Thereafter, the glass substrate was pulled out of the molten salt and gradually cooled to room temperature over 1 hour, thereby obtaining a chemically strengthened glass substrate. (2) Subsequently, this glass substrate was immersed in a 40° C. warm bath to remove the potassium nitrate adherent to surfaces of the glass substrate. (3) This glass substrate was then immersed in a solution of nitric acid (6% by mass; 40° C.) for 3 minutes to conduct an acid treatment. (4) This glass substrate was subsequently immersed in an alkali solution (Sunwash TL-75, manufactured by Lion Corp.) for 4 hours to remove a leach-out layer present in the surfaces. The amount of the leach-out layer which had been removed was calculated from glass weights respectively measured before and after the treatment for the removal of the leach-out layer and from the surface area and density of the glass. (5) Next, an antireflection film was deposited on one main surface of the glass substrate in the following manner.

First, in a vacuum chamber, pulse sputtering was conducted using a niobium oxide target (trade name, NBO Target; manufactured by AGC Ceramics Co., Ltd.) under conditions of a pressure of 0.3 Pa, frequency of 20 kHz, power density of 3.8 W/cm², and inversion pulse width of 5 μsec, while introducing a mixed gas obtained by mixing argon gas with 10% by volume of oxygen gas into a vacuum chamber, thereby forming a high-refractive-index layer containing niobium oxide (niobia) and having a thickness of 13 nm on the surface of the glass substrate. Subsequently, pulse sputtering was conducted using a silicon target under conditions of a pressure of 0.3 Pa, frequency of 20 kHz, power density of 3.8 W/cm², and inversion pulse width of 5 μsec, while introducing a mixed gas obtained by mixing argon gas with 40% by volume of oxygen gas, thereby forming a low-refractive-index layer containing silicon oxide (silica) and having a thickness of 35 nm on the high-refractive-index layer.

Next, a high-refractive-index layer containing niobium oxide (niobia) and having a thickness of 115 nm was formed on the low-refractive-index layer in the same manner as for the first layer.

Thereafter, a low-refractive-index layer containing silicon oxide (silica) and having a thickness of 90 nm was formed in the same manner as for the second layer.

Thus, an antireflection film containing a total of four stacked layers of niobium oxide (niobia) and silicon oxide (silica) was formed.

An antifouling film was formed by known methods.

### <Evaluation of the Cover Glass>

### (Luminous Reflectance)

A spectral reflectance of the surface of the cover glass was measured with a spectrophotometric colorimeter (Type CM-2600d, manufactured by Konica Minolta) in the SCI mode, and a luminous reflectance (stimulus value Y of reflection as defined in JIS Z8701:1999) was determined from a value of spectral reflectance. A back surface of the cover glass which had not undergone the antireflection treatment was painted in black in order to eliminate reflection from the back surface of the cover glass. An illuminant used for calculation was illuminant D65.

### (Degree of Ion Exchange)

An X-ray photoelectron spectrometer (Type JPS-9200, manufactured by JEOL Ltd.) was used to determine a degree of ion exchange of the surface of the cover glass using aluminum as an index. With this apparatus, a proportion of ions present can be examined along a depth direction. First, a proportion of ions present at a sufficiently large depth from the surface is calculated as a reference. In this measurement, a proportion (A) of ions present at a depth of 30 nm was taken as a reference. A proportion of aluminum ions present at a depth of 5 nm was expressed by (B), and the degree of ion exchange p was determined using the following equation.

ρ=B/A

### (Color Distribution)

First, any square portion of 10 cm² was selected from the surface of the cover glass as a measuring range, and this measuring range was divided into 11×11 equal portions, and 100 intersections in a resultant lattice pattern were examined for color in the following manner.

The spectral reflectance of the surface of the cover glass on the side where the antireflection treatment had been performed was measured with a spectrophotometric colorimeter (Type CM-2600d, manufactured by Konica Minolta) in the SCI mode, and color indexes (color indexes a* and b* as provided for in JIS Z8729:2004) were determined form a value of spectral reflectance. The back surface of the glass which had not undergone the antireflection treatment was painted in black in order to eliminate reflection from the back surface of the cover glass.

From each maximum value and each minimum value of a* and b* (a*ₘₐₓ, a*ₘᵢₙ, b*ₘₐₓ, and b*ₘᵢₙ) measured for all the 100 points, the color distribution E was determined using the following calculation formula (1-1).

E=¢{(a*ₘₐₓ−a*ₘᵢₙ)²±(b*ₘₐₓ−b*ₘᵢₙ)²} (1-1)

Subsequently, the measuring range was changed, and the same measurement as described above was repeatedly made three times in total. With respect to each measurement, a value of E was determined.

### (Contact Angle of Water)

An about 1 μL droplet of pure water was placed on the surface of the cover glass on the side where the antiglare treatment and antireflection treatment had been performed. Using a contact angle meter (device name, DM-51; manufactured by Kyowa Interface Science Co., Ltd.), the contact angle of water was measured.

### (Crack Length)

Lengths of cracks in main surfaces of the glass substrate were measured in the following manner. First, 20 cover glasses are prepared with respect to each Example. Next, the main surfaces of the glass substrates are ground with abrasive grains of cerium oxide while changing a grinding amount in stages over the cover glasses. The grinding amount for the first substrate is 0.5 μm, that for the second substrate is 1 μm, and the grinding amount is changed by 0.5 μm up to 10μm for the 20th substrate. Thereafter, the main surfaces of the glass substrates are slightly etched with a 1 mol % aqueous solution of HF. This etching opens ends of remaining cracks to make the cracks easy to recognize. The largest grinding amount in μm at which crack marks remained was determined with an optical microscope (VK-X120, manufactured by Keyence Corp.), thereby determining the crack length. For example, in cases when cracks remained until 4-μm grinding but no cracks were observed after 4.5 μm grinding, then the crack length is regarded as 4 μm. From each value of grinding amount, thicknesses of the low-reflection films and antifouling films have been excluded. Consequently, the antireflection film and the like are removed beforehand by grinding, etc. to expose the surface of the substrate.

### Example 2

A cover glass was produced in the same manner as in Example 1, except that a thickness of a substrate was changed and that acid treatment conditions were changed to a treatment with a solution of hydrochloric acid (3.6% by mass; 40° C.).

### Example 3

A cover glass was produced in the same manner as in Example 1, except that a configuration of the antireflection film was changed to a two-layer configuration and that an antifouling film was changed to OPTOOL DSX.

### Example 4

A cover glass was produced in the same manner as in Example 1, except that a configuration of an antireflection film was changed to a eight-layer configuration and that a material of each high-refractive-index layer was changed to SiN.

### Example 5

A cover glass was produced in the same manner as in Example 1, except that an acid treatment condition was changed to a treatment with a solution of sulfuric acid (10% by mass; 40° C.).

### Example 6

A cover glass was produced in the same manner as in Example 1, except that an acid treatment condition was changed to a treatment with a solution of hydrofluoric acid (2% by mass; 40° C.).

### Example 7

A cover glass was produced in the same manner as in Example 1, except that an acid treatment condition was changed to a treatment with a solution of citric acid (20% by mass; 40° C.).

### Comparative Example 1

A cover glass was produced in the same manner as in Example 1, except that an acid treatment step and a leach-out layer removal step were omitted.

### Comparative Example 2

A cover glass was produced in the same manner as in Example 7, except that a leach-out layer removal step was omitted and that an antifouling film was newly disposed.

### Comparative Example 3

A cover glass was produced in the same manner as in Example 6, except that a leach-out layer removal step was omitted and that an antifouling film was newly disposed.

The results of the evaluation of the cover glasses produced are shown in Table 1 and Table 2. In Table 1 and Table 2, the term “DT” means DRAGONTRAIL.

TABLE 1

| | Example 1 | | Example 2 | | Example 3 | | Example 4 | | Example 5 | |
|---|---|---|---|---|---|---|---|---|---|---|
| Substrate | DT | | DT | | DT | | DT | | DT | |
| Substrate | 1.3 | mm | 2 | mm | 1.3 | mm | 1.3 | mm | 1.3 | mm |
| thickness | | | | | | | | | | |
| Surface etching | 6 | wt. % | 3.6 | wt. % | 6 wt. % | | 6 | wt. % | 10 | wt. % |
| treatment | nitric acid | | hydrochloric | | nitric acid | | nitric acid | | sulfuric acid | |
| conditions | solution | | acid solution | | solution | | solution | | solution | |
| | 40° C., 3 min | | 40° C., 3 min | | 40° C., 3 min | | 40° C., 3 min | | 40° C., 3 min | |
| Leach-out layer | Sunwash | | Sunwash | | Sunwash | | Sunwash | | Sunwash | |
| removal | 4 | hr | 4 | hr | 4 | hr | 4 | hr | 4 | hr |
| conditions | | | | | | | | | | |
| Configuration of | Nb₂O₅ | | Nb₂O₅ | | Nb₂O₅ | | SiN | | Nb₂O₅ | |
| antireflection | 13 | nm | 13 | nm | 13 | nm | 15 | nm | 13 | nm |
| film | SiO₂ | | SiO₂ | | SiO₂ | | SiO₂ | | SiO₂ | |
| | 35 | nm | 35 | nm | 120 | nm | 70 | nm | 35 | nm |
| | Nb₂O₅ | | Nb₂O₅ | | | | SiN | | Nb₂O₅ | |
| | 115 | nm | 115 | nm | | | 17 | nm | 115 | nm |
| | SiO₂ | | SiO₂ | | | | SiO₂ | | SiO₂ | |
| | 90 | nm | 90 | nm | | | 105 | nm | 90 | nm |
| | | | | | | | SiN | | | |
| | | | | | | | 15 | nm | | |
| | | | | | | | SiO₂ | | | |
| | | | | | | | 50 | nm | | |
| | | | | | | | SiN | | | |
| | | | | | | | 120 | nm | | |
| | | | | | | | SiO₂ | | | |
| | | | | | | | 80 | nm | | |
| Antifouling | KY-185, | | KY-185, | | OPTOOL DSX, | | KY-185, | | — | |
| film | manufactured | | manufactured | | manufactured | | manufactured | | | |
| | by ShinEtsu | | by ShinEtsu | | by Daikin | | by ShinEtsu | | | |
| | Chemical | | Chemical | | Industries | | Chemical | | | |
| Luminous | 0.80% | | 0.80% | | 1.50% | | 1% | | 0.80% | |
| reflectance | | | | | | | | | | |
| Unevenness | 1.5 | | 2.3 | | 1.2 | | 2.5 | | 1.6 | |
| in color tone | 2.2 | | 1.9 | | 0.9 | | 2.9 | | 1.6 | |
| (E; three | 1.8 | | 2.1 | | 1.4 | | 2.8 | | 1.4 | |
| measurements) | | | | | | | | | | |
| Crack length | 2 | μM | 0.5 | μM | 2 | μM | 2 | μM | 1 | μM |

TABLE 2

| | | | | | Comparative | | Comparative | | Comparative | |
|---|---|---|---|---|---|---|---|---|---|---|
| | Example 6 | | Example 7 | | Example 1 | | Example 2 | | Example 3 | |
| Substrate | DT | | DT | | DT | | DT | | DT | |
| Substrate | 1.3 | mm | 1.3 | mm | 1.3 | mm | 1.3 | mm | 1.3 | mm |
| thickness | | | | | | | | | | |
| Surface etching | 2 | wt. % | 20 | wt. % | none | | 20 | wt. % | 2 | wt. % |
| treatment | hydrofluoric | | citric acid | | | | citric acid | | hydrofluoric | |
| conditions | acid solution | | solution | | | | solution | | acid solution | |
| | 40° C., 3 min | | 40° C., 3 min | | | | 40° C., 3 min | | 40° C., 3 min | |
| Leach-out layer | Sunwash | | Sunwash | | none | | none | | none | |
| removal | 4 | hr | 4 | hr | | | | | | |
| conditions | | | | | | | | | | |
| Configuration of | Nb₂O₅ | | Nb₂O₅ | | Nb₂O₅ | | Nb₂O₅ | | Nb₂O₅ | |
| antireflection | 13 | nm | 13 | nm | 13 | nm | 13 | nm | 13 | nm |
| film | SiO₂ | | SiO₂ | | SiO₂ | | SiO₂ | | SiO₂ | |
| | 35 | nm | 35 | nm | 35 | nm | 35 | nm | 35 | nm |
| | Nb₂O₅ | | Nb₂O₅ | | Nb₂O₅ | | Nb₂O₅ | | Nb₂O₅ | |
| | 115 | nm | 115 | nm | 115 | nm | 115 | nm | 115 | nm |
| | SiO₂ | | SiO₂ | | SiO₂ | | SiO₂ | | SiO₂ | |
| | 90 | nm | 90 | nm | 90 | nm | 90 | nm | 90 | nm |
| Antifouling | — | | — | | KY-185, | | KY-185, | | KY-185, | |
| film | | | | | manufactured | | manufactured | | manufactured | |
| | | | | | by ShinEtsu | | by ShinEtsu | | by ShinEtsu | |
| | | | | | Chemical | | Chemical | | Chemical | |
| Luminous | 0.80% | | 0.80% | | 0.80% | | 0.80% | | 0.80% | |
| reflectance | | | | | | | | | | |
| Unevenness | 2.7 | | 3.1 | | 1.7 | | 4.5 | | 5.2 | |
| in color tone | 2.4 | | 2.8 | | 2 | | 4.2 | | 4.8 | |
| (E; three | 2.5 | | 3.2 | | 1.8 | | 4.3 | | 4.6 | |
| measurements) | | | | | | | | | | |
| Crack length | less than | | 1.5 | μm | 6 | μm | 1.5 | μm | less than | |
| | 0.5 | μm | | | | | | | 0.5 | μm |

The cover glass of Comparative Example 1, in which an acid treatment step was omitted, had a crack length of exceeding 5 μm and had insufficient strength. The cover glasses of Comparative Examples 2 and 3, in which the leach-out layer removal step was omitted, each had a wide color distribution E and are thought to have unevenness in color. This is because the leach-out layer remained unremoved.

In contrast, the cover glasses of the Examples each had a small value of color distribution E, indicating that a color tone unevenness was slight. It can be seen that the removal of the leach-out layer had brought about an effect. Furthermore, in each Example, the three measurements for color distribution determination each satisfied E≤4. It can hence be seen that the evenness over the glass surface was also high.

While the present invention has been described in detail and with reference to specific embodiments thereof, it will be apparent to one skilled in the art that various changes and modifications can be made therein without departing from the spirit and scope thereof.

### DESCRIPTION OF THE REFERENCE NUMERALS AND SIGN

10 Glass substrate
10R Leach-out layer
20 Antireflection film
30 Antifouling film

1. The process according to claim 7, wherein
the at least one main surface of the glass substrate has one or more cracks formed therein, the crack(s) each having a length of 5 μm or less, and
a difference Δa* in a* value between any two points within a surface of the cover glass on a side where the antireflection film has been formed and a difference Δb* in b* value between any two points within the surface of the cover glass on the side where the antireflection film has been formed satisfy the following expression (1):
√{(Δa*)²+(Δb*)²}≤4 (1)

2. The process according to claim 7, wherein the Δa* and the Δb* are determined by selecting any square portion of 10 cm² as a measuring range from the surface of the cover glass on the side where the antireflection film has been formed, dividing the measuring range into 11×11 equal portions, examining all 100 intersections of equally dividing lines for a* values and b* values, determining a maximum value a*ₘₐₓ of the a*values, a minimum value a*ₘᵢₙ of the a*values, a maximum value b*ₘₐₓ of the b*values, and a minimum value b*ₘᵢₙ of the b*values, from the a* values and b* values, and taking a difference (a*ₘₐₓ−a*ₘᵢₙ) between the a*ₘₐₓ and the a*ₘᵢₙ as the Δa* and a difference (b*ₘₐₓ−b*ₘᵢₙ) between the b*ₘₐₓ and the b*ₘᵢₙ as the Δb*.

3. The process according to claim 7, wherein the antireflection film is a laminate comprising at least one layer containing niobium and at least one layer containing silicon.

4. The process according to claim 2, wherein the antireflection film is a laminate comprising at least one layer containing niobium and at least one layer containing silicon.

5. The process according to claim 7, wherein the cover glass has a luminous reflectance of 2% or less.

6. The process according to claim 7, further comprising:
forming an antifouling film on the antireflection film,
wherein a contact angle of water on a surface of the cover glass on a side where the antifouling film has been formed is 90° or larger.

7. A process for producing a cover glass, the process comprising:
subjecting at least one main surface of a glass substrate to an acid treatment;
subjecting the at least one main surface of the glass substrate which has been subjected to the acid treatment to an alkali treatment; and
depositing an antireflection film on the at least one main surface of the glass substrate which has been subjected to the alkali treatment.

8. The process according to claim 7, wherein the glass substrate subjected to the acid treatment has been chemically strengthened.
